(19) United States
(12) Patent Application Publication
(10) Pub. No.: US 2016/0208377 A1
(43) Pub. Date: Jul. 21, 2016

(54) TANTALUM SPUTTERING TARGET AND METHOD FOR PRODUCING SAME

(71) Applicant: JX NIPPON MINING & METALS CORPORATION, Tokyo (JP)

(72) Inventor: Kunihiro ODA, Ibaraki (JP)

(21) Appl. No.: 14/914,385

(22) PCT Filed: Mar. 4, 2015
(86) PCT No.: PCT/JP2015/056340

§ 371 Date: Feb. 25, 2016

(30) Foreign Application Priority Data
Mar. 27, 2014 (JP) 2014-065294

(51) Int. Cl. C23C 14/34; C22F 1/18; C21D 9/00; C21D 8/02; H01L 23/532; C23C 14/14; C23C 14/06; H01L 21/285; H01L 21/768; H01J 37/34; C23C 8/24

(52) U.S. Cl. CPC C23C 14/3414; H01J 37/3429; C22F 1/18; C21D 9/0062; C21D 8/0273; C21D 8/0221; C23C 8/24; C23C 14/14; C23C 14/0641; H01L 21/2855; H01L 21/28568; H01L 21/76841; H01L 23/53238

(57) ABSTRACT

A tantalum sputtering target, wherein an orientation rate of a (100) plane of a sputtering surface of the tantalum sputtering target is 30 to 90%, and an orientation rate of a (111) plane of a sputtering surface of the tantalum sputtering target is 50% or less. A method of producing a tantalum sputtering target, wherein a molten tantalum ingot is subject to forging and recrystallization annealing and thereafter subject to rolling and heat treatment in order to form a crystal structure in which an orientation rate of a (100) plane of the tantalum sputtering target is 30 to 90%, and an orientation rate of a (111) plane of the tantalum sputtering target is 50% or less.

The present invention yields effects of being able to reduce the integral power consumption for burn-in of the tantalum target, easily generate plasma, stabilize the deposition rate, and reduce the resistance variation of the film by controlling the crystal orientation of the target.

### TECHNICAL FIELD

The present invention relates to a tantalum sputtering target and a method for producing such a tantalum sputtering target. In particular, the present invention relates to a tantalum sputtering target that is used for forming a Ta film or a TaN film as a diffusion barrier layer of a copper wiring in an LSI, and to a method for producing such a tantalum sputtering target.

### BACKGROUND ART

Conventionally, aluminum was used as the wiring material for semiconductor devices, but pursuant to the miniaturization and higher integration of the devices, the problem of wiring delay became an issue, and copper having smaller electrical resistance than aluminum is now being used. While copper is extremely effective as a wiring material, since copper itself is an active metal, there is a problem in that copper diffuses in and contaminates the interlayer insulating film, and it is necessary to form a diffusion barrier layer such as a Ta film and a TaN film between the copper wiring and the interlayer insulating film.

Generally speaking, a Ta film or a TaN film is deposited by sputtering a tantalum target. As factors that affect the performance of a tantalum target during sputtering, it is known that the various impurities and gas components contained in the target, the crystal plane orientation, and crystal grain size affect the deposition rate, film thickness uniformity, generation of particles, and the like.

For example, Patent Document 1 describes improving the uniformity of the film by forming a crystal structure in which the (111) orientation is preferential from the position of 30% of the target thickness toward the central plane of the target.

Moreover, Patent Document 2 describes increasing the deposition rate and improving the uniformity of the film by causing the crystal orientation of the tantalum target to be random (no alignment to a specific crystal orientation).

Moreover, Patent Document 3 describes improving the deposition rate by selectively increasing the plane orientations of (110), (100), (211), which have a high atomic density, on the sputtering surface, and improving the uniformity by suppressing the variation in the plane orientation.

In addition, Patent Document 4 describes improving the film thickness uniformity by causing the variation in the intensity ratio of the (110) plane obtained based on X-ray diffraction, depending on the location of the sputtering surface, to be within 20%.

Moreover, Patent Document 5 describes that a round metal target having an extremely strong crystallographic texture such as (111) or (100) can be prepared by combining swaging, extrusion, rotary forging, and non-lubrication upset forging with clock rolling.

In addition, Patent Document 6 describes a method of producing a tantalum sputtering target by subjecting a tantalum ingot to forging, annealing and rolling, and, after subjecting the tantalum ingot to the final plastic working, further performing annealing thereto at a temperature of 1173 K or less to obtain a tantalum sputtering target having an unrecrystallized structure of 20% or more and 90% or less.

Moreover, Patent Document 7 discloses a technique of stabilizing the sputtering characteristics by causing the relative intensity of the peak of the sputtering surface of the target to be (110)>(211)>(100) through forging, cold rolling and other processes, and heat treatment. Generally speaking, since (110) becomes higher due to the processing strain, the sputter rate is increased as to this kind of processed surface and the surface removal via burn-in can be completed sooner, and thereby an effect is yielded in that the exposure of the stability region can be accelerated. Therefore, this kind of (110) tends to be adopted.

Moreover, Patent Document 8 describes a process comprising: forging a tantalum ingot; performing heat treatment two or more times during the foregoing forging process step; additionally performing cold rolling; and performing recrystallization heat treatment.

Moreover, Patent Document 9 describes a tantalum sputtering target containing 1 massppm or more and 100 massppm or less of molybdenum as its essential component, and having a purity of 99.998% or higher excluding molybdenum and gas components; and further describes a tantalum sputtering target additionally containing 0 to 100 massppm (but excluding 0 massppm) of niobium, and having a purity of 99.998% or higher excluding molybdenum, niobium and gas components. Patent Document 9 describes that it is possible to obtain a high purity tantalum sputtering target comprising a uniform and fine structure, which can achieve stable plasma and superior film uniformity.

In addition, Patent Document 10 describes a tantalum sputtering target containing 1 massppm or more and 100 massppm or less of tungsten, and having a purity of 99.998% or higher excluding tungsten and gas components; and further describes a tantalum sputtering target additionally containing 0 to 100 massppm (but excluding 0 massppm) of molybdenum and/or niobium, having a total content of tungsten, molybdenum, and niobium of 1 massppm or more and 150 massppm or less, and having a purity of 99.998% or higher excluding tungsten, molybdenum, niobium and gas components. Patent Document 10 describes that it is possible to obtain a high purity tantalum sputtering target comprising a uniform and fine structure, which can achieve stable plasma and superior film uniformity.

As tantalum sputtering targets for use in semiconductors, various types of targets are being developed as described above. A target material generally has a thickness of roughly 10 mm, and cost reduction is being sought by increasing the number of depositions (number of wafers) per target. Here, it could be said that increasing the thickness of the target is effective in reducing costs since it is possible to reduce the frequency of replacing the target and reduce the down time of the equipment.

In order to increase the cumulative time that the target can be used, it would be sufficient to increase the thickness of the target and enable the target to be used for a longer period, but a tantalum target has a unique problem. Generally speaking, during the sputtering of a target, a film is formed on the peripheral devices around the wafer, or a film is formed around the target due to reverse sputtering.

Thus, adopted is a method to extend deposition by causing the sputtering equipment (vacuum device) to be open to the atmosphere during the use of the target to replace the contaminated components, and then resuming sputtering.

Nevertheless, with a tantalum target that is sputtered in a high vacuum, an extremely activated surface is exposed, and when the vacuum device is open to and the target is exposed in the atmosphere, a firm oxide film is rapidly formed. The formation of this kind of oxide film is a phenomenon which occurs with the oxygen in the atmosphere, without having to intentionally introduce oxygen.

With a tantalum target formed with the foregoing oxide film, even when vacuuming is performed once again and resumption of sputtering is attempted, there are problems in that the oxide film formed on the surface causes the deposition properties to become unstable, the deposition rate becomes disturbed, and the burn-in time required for removing the surface oxide film via sputtering and exposing a newly formed stable surface of the target becomes long. Consequently, this caused the increase in the consumption of time, power and materials and deterioration in the material (deposition) characteristics. Nevertheless, none of the Patent Documents described above disclose a method for resolving this problem, and it was not even possible to find a clue for resolving this problem.

### PRIOR ART DOCUMENTS

### Patent Documents

[Patent Document 1] JP 2004-107758 A

[Patent Document 2] WO 2005/045090 A

[Patent Document 3] JP H11-080942 A

[Patent Document 4] JP 2002-363736 A

[Patent Document 5] JP 2008-532765 A

[Patent Document 6] Japanese Patent No. 4754617

[Patent Document 7] WO 2011/061897 A

[Patent Document 8] Japanese Patent No. 4714123

[Patent Document 9] WO 2011/018970 A

[Patent Document 10] WO 2011/008971 A

### SUMMARY OF INVENTION

### Technical Problem

Upon adopting the method of controlling the crystal orientation on the sputtering surface of the tantalum sputtering target to facilitate the formation of a nitride film, causing the sputtering equipment (vacuum device) to be open to the atmosphere midway during the use of the target to replace the contaminated components, and then resuming the sputtering, the present invention focused on the problem where, when the activated surface of the tantalum target is directly exposed to the atmosphere, a firm oxide film is formed.

Thus in the present invention, a nitride film is formed in advance. In other words, in the present invention, a nitride film is formed on the surface of the tantalum target before it will be open to the atmosphere. It is thereby possible to effectively suppress the formation of an oxide film caused by the rapid reaction with oxygen in the air. The present invention is thereby possible to stabilize the deposition properties and deposition rate, shorten the burn-in time, reduce the consumption of time and power, and improve the material (deposition) characteristics.

In addition, the present invention is effective in reducing costs by increasing the cumulative time of the target use, increasing the thickness of the target, and enabling the longer use of the target. Accordingly, the present invention can provide an efficient tantalum sputtering target that is useful for forming a diffusion barrier film such as a Ta film and a TaN film.

### Solution to Problem

In order to resolve the foregoing problems, the present invention provides the following invention:
1) A tantalum sputtering target, wherein an orientation rate of a (100) plane of a sputtering surface of the tantalum sputtering target is 30 to 90%, and an orientation rate of a (111) plane of a sputtering surface of the tantalum sputtering target is 50% or less.
2) The tantalum sputtering target according to 1) above, wherein the sputtering surface of the tantalum sputtering target is provided with a nitride film.
3) The tantalum sputtering target according to 2) above, wherein a thickness of the nitride film is 200 Å or more.
4) A thin film for a diffusion barrier layer formed using the sputtering target according to any one of 1) to 3) above.
5) The thin film for a diffusion barrier layer according to 4) above formed using the sputtering target, wherein a resistance variation of the sputtered film is 15% or less.
6) The thin film for a diffusion barrier layer according to 4) or 5) above formed using the sputtering target, wherein integral power consumption for burn-in is 100 kwh or less.
7) A semiconductor device comprising the thin film for a diffusion barrier layer according to any one of 4) to 6) above.

The present invention additionally provides the following invention.
8) A method of producing a tantalum sputtering target, wherein a molten tantalum ingot is subject to forging and recrystallization annealing and thereafter subject to rolling and heat treatment in order to form a crystal structure in which an orientation rate of a (100) plane of the tantalum sputtering target is 30 to 90%, and an orientation rate of a (111) plane of the tantalum sputtering target is 50% or less.
9) The method of producing a tantalum sputtering target according to 8) above, wherein a sputtering operation to a target scheduled to be reused in sputtering is paused, and, before causing a vacuum vessel to be open to the atmosphere, nitrogen gas is supplied onto a surface of the target to form a nitride film.
10) The method of producing a tantalum sputtering target according to 9) above, wherein a thickness of the nitride film to be formed is 200 Å or more.

### Advantageous Effects of Invention

The present invention provides a tantalum sputtering target, and the formation of a nitride film on the tantalum target surface can be facilitated by controlling the crystal orientation on the sputtering surface of the target. Consequently, when adopting the method of causing the sputtering equipment (vacuum device) to be open to the atmosphere midway during the use of the target to replace the contaminated components and then resuming sputtering, even if the activated surface of the tantalum target is exposed in the atmosphere, it is possible suppress the formation of a firm oxide film, stabilize the deposition properties and deposition rate, shorten the burn-in time, reduce the consumption of time and power, and achieve favorable material (deposition) characteristics.

Consequently, since it is thereby possible to increase the thickness of the target and increase the cumulative time of the target use, and the target can be used for a longer period of time, the present invention is extremely effective in reducing the cost of using the target. The present invention can thus provide an efficient tantalum sputtering target that is useful in forming a diffusion barrier film such as a Ta film and a TaN film.

Note that the integral power consumption for burn-in is the electric power represented as kWh obtained by multiplying the input power “kW” during the burn-in by the sputter time “h”. Since the input power and sputter time are normally managed with a sputtering equipment, sputtering is basically and consistently managed based on integral power.

### DESCRIPTION OF EMBODIMENTS

The tantalum sputtering target of the present invention is sputtered based on standard processes. But, the present invention is unique in that, with a target having such crystal plane orientation rates that the (100) plane orientation rate is 30 to 90% and the (111) plane orientation rate is 50% or less, a nitride film can be easily formed thereon by using nitrogen gas when the sputtering equipment (vacuum device) is open to the atmosphere midway during the use of the target to replace the contaminated components and then sputtering is resumed.

In addition, a nitride film that is formed in advance is able to resolve the conventional problems because it can effectively suppress the formation of an oxide film caused by the rapid reaction with oxygen in the air.

Since the tantalum target of the present invention having such crystal plane orientation rates that the (100) plane orientation rate is 30 to 90% and the (111) plane orientation rate is 50% or less, comprises a unique orientation as a tantalum target, it could be said that this tantalum target is in itself novel as a tantalum target. A tantalum target normally has a thickness of 5 mm or more.

Based on the above, before pausing the sputtering operation to a target scheduled to be reused (used again) in sputtering and causing the vacuum vessel to be open to the atmosphere, nitrogen gas is supplied onto the surface of the target to form a nitride film, and the thickness of the nitride film is caused to be 200 Å or more.

Upon forming a nitride film, the nitride film can be formed by supplying nitrogen gas to the surface of the target before pausing the sputtering operation to a target scheduled to be reused in sputtering and causing the vacuum vessel to be open to the atmosphere.

A sputtering equipment comprises separate supply lines for N₂ and Ar; however, the purpose of this operation is for nitriding the surface, and Ar mixed gas is not required since sputtering is not performed during this operation, and therefore only nitrogen gas is supplied. N₂ gas containing 1% of Ar may also be used as needed.

Upon replacing the contaminated components and resuming sputtering, in the tantalum sputtering target provided with a nitride film on its surface, the nitride film can effectively suppress the formation of an oxide film, and the burn-in time when reusing it can be kept relatively short. Accordingly, the present invention yields the effects of being able to reduce the consumption of time and power and the materials that are consumed during the burn-in, and improve the deposition properties. Consequently, it is possible to increase the thickness of the tantalum target and increase the cumulative time of the target use, and the target can be used for a longer period of time. Thus, it can be said that the present invention is extremely effective in reducing the cost of using the target.

Accordingly, it is possible to cause the resistance variation of the tantalum sputtered film formed during reuse of the tantalum target to be 15% or less of that before pausing the use of the tantalum target, and also realize an integral power consumption for burn-in of 100 kwh or less. This kind of thin film for a diffusion barrier layer is effective in the production of semiconductor devices. Note that the resistance variation is obtained by comparing the sheet resistance of the film-deposited wafer before and after the sputtering equipment is open to the atmosphere, and sheet resistance after the sputtering equipment is open to the atmosphere is desirably within the range of 85% to 115% of the sheet resistance before the sputtering equipment is open to the atmosphere.

In order to form a crystal structure in which the orientation rate of the (100) plane of the tantalum sputtering target is 30 to 90% and the orientation rate of the (111) plane of the tantalum sputtering target is 50% or less, forging and recrystallization annealing are performed under the condition of repeating the cycle of forging-annealing of the molten tantalum ingot two or more times, preferably three times or more, and rolling and heat treatment are thereafter performed. Note that the (100) plane or the (111) plane includes all parts that are exposed from the target surface to the inside thereof from the initial stage of sputtering to the final stage of sputtering.

The tantalum sputtering target of the present invention may be used for forming a diffusion barrier layer such as a Ta film and a TaN film in a copper wiring. Even in cases of introducing nitrogen into the sputtering atmosphere to deposit a TaN film, the sputtering target of the present invention yields superior effects of being able to reduce the discharge voltage of the tantalum target by controlling the crystal orientation on the sputtering surface of the target so that plasma can be more easily generated and the stability of plasma can be improved. Thus, the present invention can improve the production yield in the formation of copper wirings comprising a diffusion barrier layer such as a Ta film and a TaN film, and in the manufacture of semiconductor devices comprising such a copper wiring.

The tantalum sputtering target of the present invention is produced according to the following processes. To illustrate an example, foremost, high purity tantalum having a purity of 4N (99.99%) or higher is normally used as the tantalum raw material. The tantalum raw material is melted via electron beam melting or the like and subsequently cast to prepare an ingot or a billet. Subsequently, the ingot or the billet is subject to forging, and recrystallization annealing. Specifically, for example, the ingot or the billet is subject to press forging—annealing at a temperature of 1100 to 1400° C.—cold forging (primary forging)—annealing at a temperature of recrystallization temperature to 1400° C.—cold forging (secondary forging)—annealing at a temperature of recrystallization temperature to 1400° C.

Cold rolling is subsequently performed. The orientation rate of the tantalum sputtering target of the present invention can be controlled by adjusting the cold rolling conditions. Specifically, a rolling mill roll with a small roll diameter should be used, and preferably the roll diameter is 500 mmφ or less. Moreover, the rolling speed should be as slow as possible, and preferably 10 m/min or less. In addition, when rolling is only performed once, the rolling reduction is preferably high and in excess of 80%; and when rolling is to be repeated two or more times, the rolling reduction needs to be 60% or higher so that the ultimate thickness of the target becomes the same as the case of performing rolling only once. Desirably, the total amount of rolling reduction exceeds 80%. Moreover, the configuration should be designed so that the rolling reduction at 1 pass does not exceed 10%.

Heat treatment is subsequently performed. The orientation rate of the tantalum sputtering target of the present invention can be controlled by adjusting the conditions of the heat treatment performed after cold rolling in addition to adjusting the cold rolling conditions. Specifically, the heat treatment temperature should be high, and preferably 800 to 1200° C. While this will also depend on the amount of strain that is introduced from the rolling process, heat treatment needs to be performed at a temperature of 800° C. or higher in order to obtain a recrystallized structure. Meanwhile, to perform heat treatment at a temperature that exceeds 1200° C. is undesirable because it would assist the growth of coarse grains and in terms of cost. Subsequently, the surface of the target is subject to surface finishing via machining or polishing in order to obtain the final product.

The tantalum target is produced based on the foregoing production processes, but what is particularly important in the present invention is to increase the orientation rate of the (100) plane and decrease the orientation rate of the (111) plane in the crystal orientation on the sputtering surface of the target.

The rolling process is mainly responsible for controlling the orientation. In the rolling process, it is possible to change the amount and distribution of strain that is introduced from the rolling process by controlling parameters such as the diameter of the rolling mill roll, rolling speed, and rolling reduction, and the orientation rate of the (100) plane and the orientation rate of the (111) plane can thereby be controlled.

In order to effectively adjust the plane orientation rate, the condition setting needs to be repeated a certain number of times, but once the orientation rate of the (100) plane and the orientation rate of the (111) plane are adjusted, targets having constant characteristics (characteristics of a constant level) can be produced by setting the manufacturing conditions.

Upon producing a target having the orientation characteristics of the present invention, it is effective to use a rolling mill roll having a roll diameter of 500 mm or less, set the rolling speed to 10 m/min or less, and set the rolling reduction at 1 pass to 10% or less. Nevertheless, the production process is not necessarily limited to the foregoing production process so as long as the production process can achieve the crystal orientation of the present invention. In the series of processes, a condition setting of destroying the cast structure via forging and rolling and sufficiently performing recrystallization is effective.

In addition, after subjecting the molten tantalum ingot or billet to forging, rolling and other processes, the product is desirably subject to recrystallization annealing to obtain a fine and uniform structure.

### EXAMPLES

The present invention is now explained based on the Examples. The following Examples are provided to facilitate the understanding of the present invention, and the present invention is not in any way limited by these Examples. In other words, modifications and other examples based on the technical concept of the present invention are obviously covered by the present invention.

A tantalum raw material having a purity of 99.995% was subject to electron beam melting and casting to obtain an ingot having a diameter of 195 mmφ. Subsequently, the ingot was subject to press forging at room temperature to obtain a diameter of 150 mmφ, and the product was subject to recrystallization annealing at a temperature of 1100 to 1400° C.

The product was repeatedly subject to extend forging—upset forging at room temperature to obtain a thickness of 100 mm and a diameter of 150 mmφ (primary forging), and the product was subject to recrystallization annealing at a temperature of recrystallization temperature to 1400° C. In addition, the product was repeatedly subject to extend forging—upset forging at room temperature to obtain a thickness of 70 to 100 mm and a diameter of 150 to 185 mmφ (secondary forging), and the product was subject to recrystallization annealing at a temperature of recrystallization temperature to 1400° C. to obtain a target material.

### Example 1

In Example 1, the obtained target material was subject to cold rolling using a rolling mill roll having a roll diameter of 400 mm at a rolling speed of 10 m/min, rolling reduction of 86%, and maximum rolling reduction at 1 pass of 10% to obtain a thickness of 14 mm and a diameter of 520 mmφ. The product was thereafter subject to heat treatment at a temperature of 1000° C. Subsequently, the surface of the product was machined and polished to obtain a target.

Based on the foregoing processes, it was possible to obtain a tantalum sputtering target having a crystal structure in which the orientation rate of the (100) plane is 30% and the orientation rate of the (111) plane is 50%. Sputtering was performed using the obtained sputtering target.

Next, sputtering was paused at the time that the thickness of the deepest eroded part of the target reached roughly 8 mm, and nitrogen gas was introduced into the sputtering equipment (vacuum vessel) for 60 seconds. A nitride film having a thickness of roughly 200 Å was formed on the surface of the target thereby.

Subsequently, the sputtering equipment was open to the atmosphere, and the internal components were replaced and washed. The sputtering equipment was thereafter once again hermetically sealed to resume sputtering. The electrical power for the burn-in was low at 75 kwh and sputtering could be resumed in a short time. The resistance variation of the film after sputtering was 14%, and there was no change in the film properties.

The tantalum film was deposited under the following conditions (the same shall apply to the following Examples and Comparative Examples).

### <Deposition Conditions>

Power source: DC system

Electrical power: 15 kW

Ultimate vacuum: 5×10 ⁻⁸ Torr

Atmosphere gas composition: Ar

Sputter gas pressure: 5×10⁻³ Torr

Sputtering time: 15 seconds

### Example 2

In Example 2, the obtained target material was subject to cold rolling using a rolling mill roll having a roll diameter of 400 mm at a rolling speed of 8 m/min, rolling reduction of 88%, and maximum rolling reduction at 1 pass of 10% to obtain a thickness of 14 mm and a diameter of 520 mmφ. The product was thereafter subject to heat treatment at a temperature of 900° C. Subsequently, the surface of the product was machined and polished to obtain a target.

Based on the foregoing processes, it was possible to obtain a tantalum sputtering target having a crystal structure in which the orientation rate of the (100) plane is 50% and the orientation rate of the (111) plane is 20%. Sputtering was performed using the obtained sputtering target.

Next, sputtering was paused at the time that the thickness of the deepest eroded part of the target reached roughly 8 mm, and nitrogen gas was introduced into the sputtering equipment (vacuum vessel) for 60 seconds. A nitride film having a thickness of roughly 320 Å was formed on the surface of the target thereby.

Subsequently, the sputtering equipment was open to the atmosphere, and the internal components were replaced and washed. The sputtering equipment was thereafter once again hermetically sealed to resume sputtering. The electrical power for the burn-in was low at 50 kwh and sputtering could be resumed in a short time. The resistance variation of the film after sputtering was 10%, and there was no change in the film properties.

### Example 3

In Example 3, the obtained target material was subject to cold rolling using a rolling mill roll having a roll diameter of 400 mm at a rolling speed of 5 m/min, rolling reduction of 85%, and maximum rolling reduction at 1 pass of 10% to obtain a thickness of 14 mm and a diameter of 520 mmφ. The product was thereafter subject to heat treatment at a temperature of 1100° C. Subsequently, the surface of the product was machined and polished to obtain a target.

Based on the foregoing processes, it was possible to obtain a tantalum sputtering target having a crystal structure in which the orientation rate of the (100) plane is 70% and the orientation rate of the (111) plane is 15%. Sputtering was performed using the obtained sputtering target.

Next, sputtering was paused at the time that the thickness of the deepest eroded part of the target reached roughly 8 mm, and nitrogen gas was introduced into the sputtering equipment (vacuum vessel) for 60 seconds. A nitride film having a thickness of roughly 450 Å was formed on the surface of the target thereby.

Subsequently, the sputtering equipment was open to the atmosphere, and the internal components were replaced and washed. The sputtering equipment was thereafter once again hermetically sealed to resume sputtering. The electrical power for the burn-in was low at 35 kwh and sputtering could be resumed in a short time. The resistance variation of the film after sputtering was 7%, and there was no change in the film properties.

### Example 4

In Example 4, the obtained target material was subject to cold rolling using a rolling mill roll having a roll diameter of 500 mm at a rolling speed of 5 m/min, rolling reduction of 90%, and maximum rolling reduction at 1 pass of 5% to obtain a thickness of 14 mm and a diameter of 520 mmφ. The product was thereafter subject to heat treatment at a temperature of 800° C. Subsequently, the surface of the product was machined and polished to obtain a target.

Based on the foregoing processes, it was possible to obtain a tantalum sputtering target having a crystal structure in which the orientation rate of the (100) plane is 90% and the orientation rate of the (111) plane is 5%. Sputtering was performed using the obtained sputtering target.

Next, sputtering was paused at the time that the thickness of the deepest eroded part of the target reached roughly 8 mm, and nitrogen gas was introduced into the sputtering equipment (vacuum vessel) for 60 seconds. A nitride film having a thickness of roughly 500 Å was formed on the surface of the target thereby.

Subsequently, the sputtering equipment was open to the atmosphere, and the internal components were replaced and washed. The sputtering equipment was thereafter once again hermetically sealed to resume sputtering. The electrical power for the burn-in was low at 25 kwh and sputtering could be resumed in a short time. The resistance variation of the film after sputtering was 5%, and there was no change in the film properties.

### Comparative Example 1

In Comparative Example 1, the obtained target material was subject to cold rolling using a rolling mill roll having a roll diameter of 400 mm at a rolling speed of 5 m/min, rolling reduction of 85%, and maximum rolling reduction at 1 pass of 10% to obtain a thickness of 14 mm and a diameter of 520 mmφ. The product was thereafter subject to heat treatment at a temperature of 1100° C. Subsequently, the surface of the product was machined and polished to obtain a target.

Based on the foregoing processes, it was possible to obtain a tantalum sputtering target having a crystal structure in which the orientation rate of the (100) plane is 70% and the orientation rate of the (111) plane is 15%. Sputtering was performed using the obtained sputtering target.

Next, sputtering was paused at the time that the thickness of the deepest eroded part of the target reached roughly 8 mm, and the sputtering equipment was open to the atmosphere, and the internal components were replaced and washed. The sputtering equipment was thereafter once again hermetically sealed to resume sputtering. The electrical power for the burn-in was low at 300 kwh and sputtering could be resumed in a short time. The resistance variation of the film after sputtering was 35%, and change in the film properties became greatest. The reason for this is considered to be because a nitride film was not formed and oxidation progressed rapidly.

### Comparative Example 2

In Comparative Example 2, the obtained target material was subject to cold rolling using a rolling mill roll having a roll diameter of 500 mm at a rolling speed of 15 m/min, rolling reduction of 78%, and maximum rolling reduction at 1 pass of 15% to obtain a thickness of 14 mm and a diameter of 520 mmφ. The product was thereafter subject to heat treatment at a temperature of 800° C. Subsequently, the surface of the product was machined and polished to obtain a target.

Based on the foregoing processes, it was possible to obtain a tantalum sputtering target having a crystal structure in which the orientation rate of the (100) plane is 20% and the orientation rate of the (111) plane is 60%. This crystal orientation deviated from the present invention. Sputtering was performed using the obtained sputtering target.

Next, sputtering was paused at the time that the thickness of the deepest eroded part of the target reached roughly 8 mm, and nitrogen gas was introduced into the sputtering equipment (vacuum vessel) for 60 seconds. A nitride film having a thickness of roughly 150 Å was formed on the surface of the target thereby.

Subsequently, the sputtering equipment was open to the atmosphere, and the internal components were replaced and washed. The sputtering equipment was thereafter once again hermetically sealed to resume sputtering. The electrical power for the burn-in increased to 275 kwh and much time was required until normal sputtering could be performed. Moreover, the resistance variation of the film after sputtering was 32% and the change in the film properties was great, and the results were unfavorable. This is considered to be because the crystal orientation rate was inappropriate.

### Comparative Example 3

In Comparative Example 3, the obtained target material was subject to cold rolling using a rolling mill roll having a roll diameter of 400 mm at a rolling speed of 5 m/min, rolling reduction of 85%, and maximum rolling reduction at 1 pass of 10% to obtain a thickness of 14 mm and a diameter of 520 mmφ. The product was thereafter subject to heat treatment at a temperature of 1100° C. Subsequently, the surface of the product was machined and polished to obtain a target.

Based on the foregoing processes, it was possible to obtain a tantalum sputtering target having a crystal structure in which the orientation rate of the (100) plane is 70% and the orientation rate of the (111) plane is 15%. Sputtering was performed using the obtained sputtering target.

Next, sputtering was paused at the time that the thickness of the deepest eroded part of the target reached roughly 8 mm, and nitrogen gas was introduced into the sputtering equipment (vacuum vessel) for 30 seconds. A nitride film having a thickness of roughly 150 Å was formed on the surface of the target thereby.

Subsequently, the sputtering equipment was open to the atmosphere, and the internal components were replaced and washed. The sputtering equipment was thereafter once again hermetically sealed to resume sputtering. The electrical power for the burn-in increased to 105 kwh, and much time was required until normal sputtering could be performed. Moreover, the resistance variation of the film after sputtering was 24% and the change in the film properties also increased. This is considered to be because the nitrogen flow time for forming the nitride film was insufficient.

As shown in the foregoing Examples and Comparative Examples, those within the scope of conditions of the present invention were able to stabilize the deposition properties and deposition rate of the tantalum target, as well as shorten the burn-in time, reduce the consumption of the time and power, and achieve favorable material (deposition) characteristics. Moreover, it is possible to yield superior effects of being able to suppress the variation in the discharge voltage and reduce the rate of occurrence of abnormal discharge.

### INDUSTRIAL APPLICABILITY

The present invention provides a tantalum sputtering target, and, by controlling the crystal orientation on the sputtering surface of the target, the formation of a nitride film on the tantalum target surface can be facilitated. Consequently, when adopting the method of causing the sputtering equipment (vacuum device) to be open to the atmosphere midway during the use of the target to replace the contaminated components and then resuming sputtering, even if the activated surface of the tantalum target is exposed in the atmosphere, it is possible to suppress the formation of a firm oxide film, stabilize the deposition properties and deposition rate, shorten the burn-in time, reduce the consumption of time and power, and achieve favorable material (deposition) characteristics. Since it is thereby possible to increase the thickness of the target and increase the cumulative time of the target use, and the target can be used for a longer period of time, the present invention is extremely effective in reducing the cost of using the target. The present invention can thus provide an efficient tantalum sputtering target that is useful in forming a diffusion barrier film such as a Ta film and a TaN film.

1. A tantalum sputtering target, wherein an orientation rate of a (100) plane of a sputtering surface of the tantalum sputtering target is 30 to 90%, and an orientation rate of a (111) plane of a sputtering surface of the tantalum sputtering target is 50% or less.

2. The tantalum sputtering target according to claim 1, wherein the sputtering surface of the tantalum sputtering target is provided with a nitride film.

3. The tantalum sputtering target according to claim 2, wherein a thickness of the nitride film is 200 Å or more.

4. A thin film for a diffusion barrier layer formed using the sputtering target according to claim 1.

5. The thin film for a diffusion barrier layer according to claim 4 formed using the sputtering target, wherein a resistance variation of the sputtered film is 15% or less.

6. The thin film for a diffusion barrier layer according to claim 4 formed using the sputtering target, wherein integral power consumption for burn-in is 100 kwh or less.

7. A semiconductor device comprising the thin film for a diffusion barrier layer according to claim 4.

8. A method of producing a tantalum sputtering target, wherein a molten tantalum ingot is subject to forging and recrystallization annealing and thereafter subject to rolling and heat treatment in order to form a crystal structure in which an orientation rate of a (100) plane of the tantalum sputtering target is 30 to 90%, and an orientation rate of a (111) plane of the tantalum sputtering target is 50% or less.

9. The method of producing a tantalum sputtering target according to claim 8, wherein a sputtering operation to a target scheduled to be reused in sputtering is paused, and, before causing a vacuum vessel to be open to the atmosphere, nitrogen gas is supplied onto a surface of the target to fon n a nitride film.

10. The method of producing a tantalum sputtering target according to claim 9, wherein a thickness of the nitride film is 200 Å or more.
